(19) United States
(12) Patent Application Publication
(10) Pub. No.: US 2015/0200355 A1
(43) Pub. Date: Jul. 16, 2015

(54) FABRICATING A VIA

(71) Applicant: Allegro Microsystems, LLC, Worcester, MA (US)

(72) Inventors: David G. Erie, Cottage Grove, MN (US); Ruediger Held, Minneapolis, MN (US)

(73) Assignee: Allegro Microsystems, LLC, Worcester, MA (US)

(21) Appl. No.: 14/155,992

(22) Filed: Jan. 15, 2014

(51) Int. Cl. H01L 43/08; H01L 43/12; H01L 23/532; H01L 43/02; H01L 21/768; H01L 23/522

(52) U.S. Cl. CPC H01L 43/08; H01L 21/7684; H01L 21/76879; H01L 23/5226; H01L 23/53257; H01L 23/5329; H01L 43/02; H01L 43/12

(57) ABSTRACT

In one aspect, a method of fabricating a via in a hole of an isolation material includes depositing a first conductive material in the hole of the isolation material, removing a portion of the first conductive material deposited in the hole, depositing a second conductive material on the first conductive material in the hole and removing, using chemical-mechanical polishing (CMP), a portion of the second conductive material deposited on the first conductive material.

### BACKGROUND

Integrated circuits are a common feature in modem electronics. Integrated circuits generally have multiple layers of isolation material, with conductive channels connecting components on those layers. The components are electrically insulated from one another by the isolation material, and only electrically connected as intended through the conductive channels. Advances in integrated circuits over the past several decades have brought increasing complexity and decreased size.

Vias are pathways used to electrically connect layers in integrated circuits. For example, vias interconnect channels of conductor materials that are separated by insulating layers. Thus, a component on one layer of isolation material may be connected to a component on a separate layer.

Vias, also known as plugs or interconnects, are generally formed by depositing a conductive, refractory metal into a hole of the isolation material. After deposition of the metal into the hole, protruding deposited metal that extends beyond the hole is removed. Often, this removal is accomplished using chemical-mechanical polishing (CMP). CMP polishes substances at different rates, depending on the characteristics of the substance.

### SUMMARY

In one aspect, a method of fabricating a via in a hole of an isolation material includes depositing a first conductive material in the hole of the isolation material, removing a portion of the first conductive material deposited in the hole, depositing a second conductive material on the first conductive material in the hole and removing, using chemical-mechanical polishing (CMP), a portion of the second conductive material deposited on the first conductive material.

In another aspect, a via, disposed in a hole of an isolation material having a first surface, includes a first conductive material disposed in the hole and a second conductive material disposed on the first conductive material in the hole, the first and second conductive material forming an electrical connection.

In a further aspect, a semiconductor device includes a silicon dioxide layer having a first surface and a second surface opposite the first surface and a via disposed in a hole of the silicon dioxide layer. The via includes a tungsten material disposed in the hole and a titanium nitride material disposed on the tungsten material. The tungsten material and the titanium nitride material form an electrical connection. The semiconductor device further includes an aluminum copper layer disposed along the first surface of the silicon dioxide layer and electrically connected to the tungsten material and a magnetoresistive element disposed along the second surface of the silicon dioxide layer and electrically connected to the titanium nitride material.

### BRIEF DESCRIPTION OF THE DRAWINGS

FIG. 1A is a diagram of an integrated circuit (IC) having a via;

FIG. 1B is a cross-sectional diagram of the IC taken along line 2-2 of FIG. 1A;

FIG. 2 is a flowchart of an example of a process to fabricate the via;

FIG. 3 is a cross-sectional diagram of the IC before deposition of a first conductive material;

FIG. 4 is a cross-sectional diagram of the IC after deposition of the first conductive material;

FIG. 5 is a cross-sectional diagram of the IC after a first chemical-mechanical polishing (CMP);

FIG. 6 is a cross-sectional diagram along line 6-6 of FIG. 5 depicting the dishing in the first conductive material;

FIG. 7 is a cross-sectional diagram of the IC after deposition of a second conductive material; FIG. 8 is a cross-sectional diagram of the IC after a second chemical-mechanical polishing;

and

FIG. 9 is a cross-sectional diagram of the IC after a trace is added.

### DETAILED DESCRIPTION

Often, vias are formed with a conductive material that polishes faster than the surrounding dielectric. When such materials are used, chemical-mechanical polishing (CMP) forms “dishing.”

Dishing occurs when the conductive material in the center of a via will polish further than the conductive material at the edge of the via, adjacent to the dielectric.

Additionally, during the deposition of the conductive material in to the hole, the bottom and edges may fill before the center. Frequently, a center cavity will form, where conductive material is not present.

CMP may also form roughness in abraded substances. For example, in abraded structures with amorphous crystalline compositions such as metals grown from a seed layer, CMP may form rough finishes.

Roughness, cavity formation, and dishing are typically undesirable effects. For example, where a via is to be attached to a component that requires that the via be flush or flat, these three undesirable effects may introduce failures. Giant magnetoresistance (GMR) devices, for example, often require flat, smooth substrates. Others devices that may require flat, smooth substrates include but are not limited to an anisotropic magnetoresistance (AMR) element, a spin valve, a tunneling magnetoresistance (TMR) element, a magnetic tunnel junction (MTJ) element and so forth.

Described herein are techniques that mitigate or reduce the undesirable effects of roughness, cavity formation and dishing formed while fabricating the via.

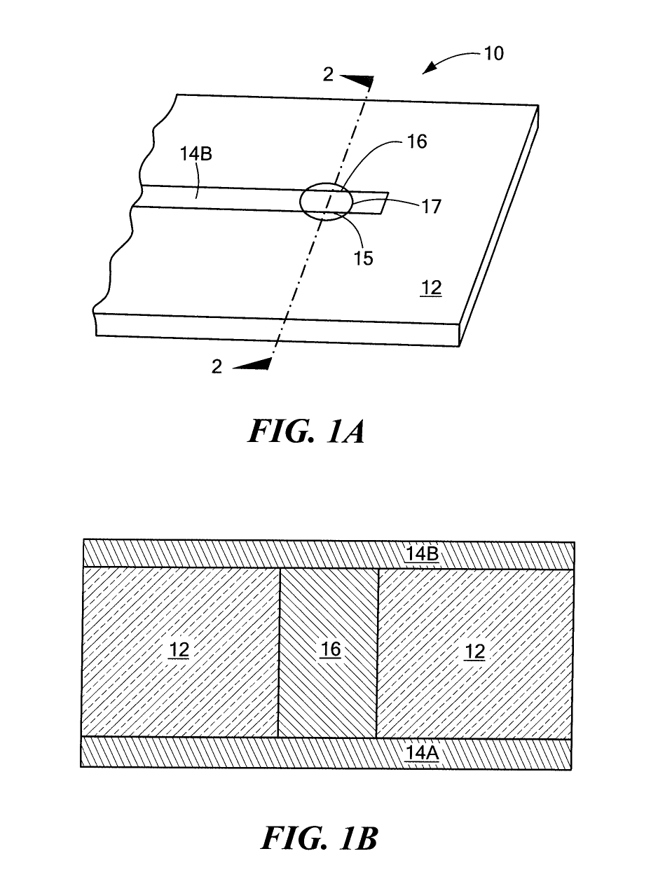

Referring to FIGS. 1A and 1B, an integrated circuit 10 includes an isolation material 12, traces 14A, 14B and a via 16 that fills a hole 15. As used herein a trace is a conductive structure that includes one or more conductive or semiconductor material. For example, the traces 14A, 14B may be made of copper, or made of a semiconductor with a relatively higher charge carrier density than the underlying portion of the isolation material 12. In one particular example, trace 14A is aluminum copper. In one embodiment the trace 14B may be a giant magnetoresistive (GMR) element, or other magnetoresistive element forming an AMR element, a spin valve, a TMR element, or an MTJ element. In one particular example, the magnetoresistive element is a stack of layers that includes at least one of nickel iron (NiFe), cobalt iron (CoFe), copper, platinum manganese (PtMn), tantalum, or ruthenium.

The IC 10 in FIGS. 1A and 1B is a simplified IC intended only to provide a perspective of the components involved in fabrication of a via. In one example, the isolation material 12 is a dielectric such as an oxide, for example. In one example, the isolation material is a silicon oxide, for example, silicon dioxide. In other examples, the isolation material 12 is silicon nitride. In some examples, the isolation material 12 is made of a semiconductor material such as a silicon or gallium arsenide. In other examples, the isolation material 12 may be aluminum oxide (Al₂O₃) (alumina).

The trace 14A is formed on a bottom surface of the isolation material 12 and the trace 14B is deposited on a top surface of the isolation material 12. The via 16 is used to electrically connect the trace 14A to the trace 14B.

The via 16 is a plug that fills in a hole 15 in the isolation material 12. For example, the via 16 passes through the hole in the isolation material 12, defined by the border 17 at the surface of the isolation material 12.

Other components which are not shown in FIG. 1 may be incorporated in alternative embodiments. For example, the integrated circuit 10 may include a GMR component, resistors, transistors, capacitors, and/or additional layers of isolation material 12, among other components which will be recognized by those of ordinary skill in the art. Many of these components, such as GMR components, require that the integrated circuit 10 have a flat top surface profile, in order to properly integrate those components.

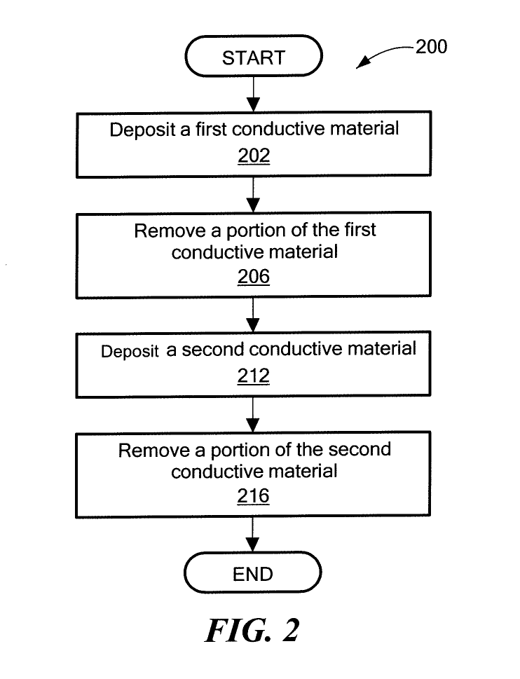

Referring to FIG. 2, an example of a process to fabricate the via 16 in FIG. 1 is a process 200. Process 200 deposits a first conductive material in a hole of an isolation material and on a surface of the dielectric material (202). For example, using vapor deposition a first conductive material is deposited in the hole 15 and on the surface of the isolation material 12. As used herein, vapor deposition means but is not limited to sputtering, physical vapor deposition (PVD), plasma enhanced chemical vapor deposition (CVD) or evaporation. As recognized by one of ordinary skill in the art, other forms of deposition may be used other than vapor deposition.

Process 200 removes a portion of the first conductive material (206). For example, using CMP the first conductive material on the isolation material 12 and a portion of the first conductor material in the hole 15 are removed (e.g., polished).

Process 200 deposits a second conductive material in the hole (e.g., a recess or depression) of an isolation material and on the surface of the dielectric material (212). For example, using vapor deposition a second conductive material is deposited in the hole 15 and on the surface of the isolation material 12. As recognized by one of ordinary skill in the art, other forms of deposition may be used other than vapor deposition.

Process 200 removes a portion of the second conductive material (216). For example, using CMP the second conductive material on the isolation material 12 and a portion of the second conductive material in the hole 15 is removed. The remaining portions of the first conductive material and the second conductive material form the via 16.

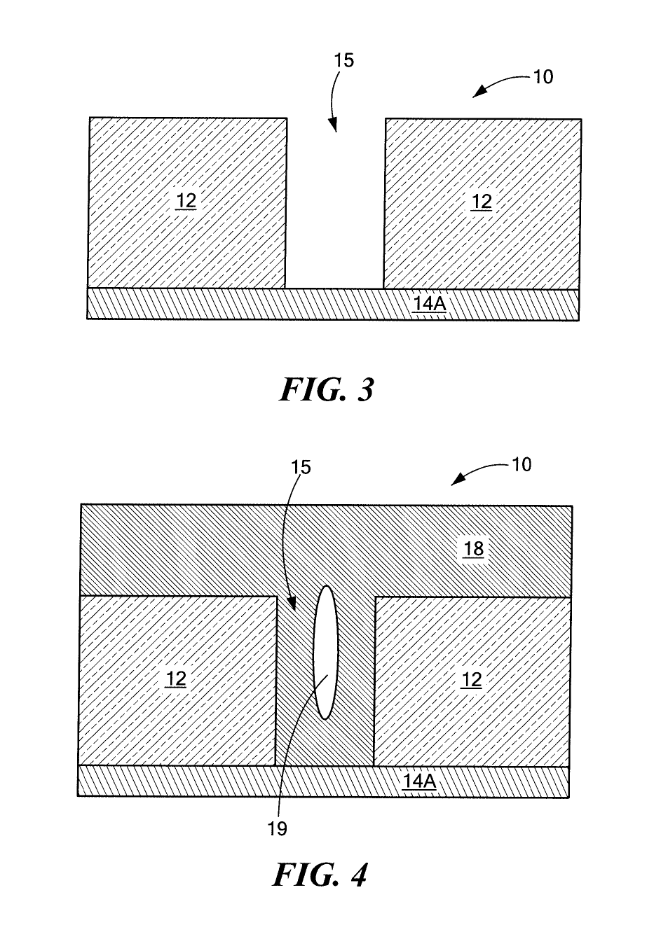

As will be shown further herein FIGS. 3 to 8 provide a specific example of implementing the process 200 to form the via 16. FIG. 3 depicts the isolation material 12 with the hole 15 empty.

FIG. 4 depicts the isolation material 12 after deposition of a first conductive material 18. During deposition, some portion of first conductive material 18 is deposited within the border 17, and at least partially fills the hole 15. Another portion of first conductive material 18 is deposited outside the region bounded by the border 17 to cover the isolation material 12. Often, the first conductive material 18 includes a cavity 19. In one example, the first conductive material 18 is at least one of tungsten and titanium nitride. In one particular example, the first conductive material 18 is tungsten. In one particular example, the deposition of the first conductive material 18 is performed using a plasma enhanced CVD process.

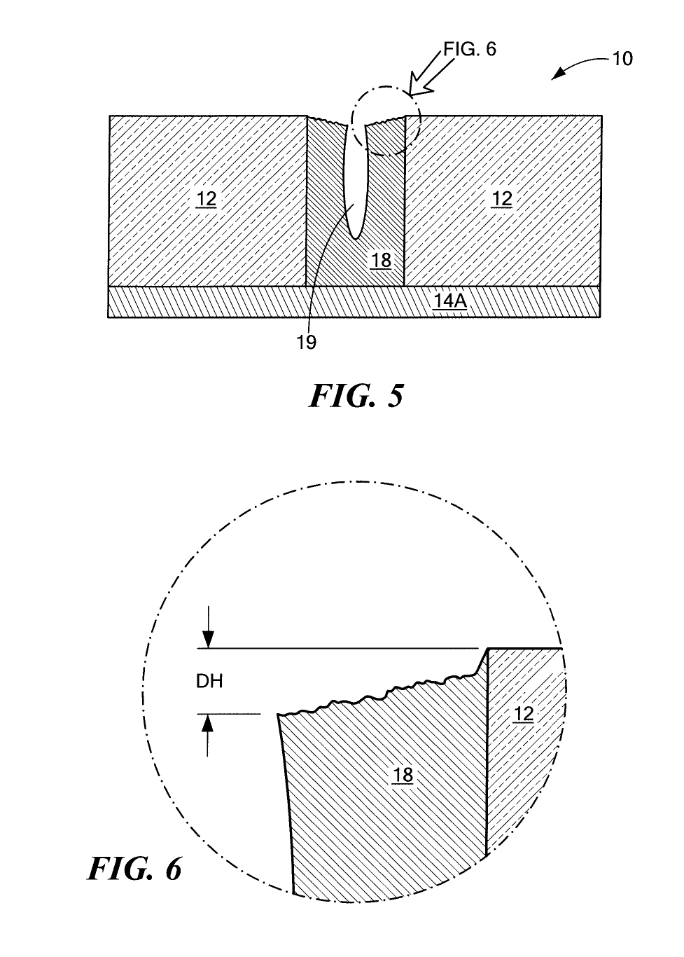

FIG. 5 depicts the isolation material 12 after CMP of the first conductive material 18. CMP, as previously described, involves mechanically polishing material away along a surface. The rate of removal of a material by CMP depends on characteristics of that material such as hardness, shear modulus, and whether the material is crystalline. For example, isolation material 12 is polished away at a lower rate than many materials used to form the via 16. For example, first conductive material 18 may be made of tungsten, and isolation material 12 may be made of undoped silicon oxide. Since tungsten is removed more quickly by CMP than undoped silicon oxide, tungsten sections will exhibit dishing, as compared to the undoped silicon oxide.

As shown in FIG. 5, the first conductive material 18 is no longer present outside the region bounded by the border 17, having been removed by CMP. Within the border 17, dishing effects have left the first conductive material 18 uneven along the surface of isolation material 12. In particular, the first conductive material 18 is dished and uneven, while typically still exhibiting at least a portion of the cavity 19. The integrated circuit 10 in FIG. 5 includes undesirable features for a finished integrated circuit, in that roughness, dishing, and the cavity exist. Referring to FIG. 6, the removal of the first conductive material 18 forms a dishing feature.

Dishing is sometimes measured using a dish height, DH, measured from the portion of the material at the center of the hole (i.e., a bottom of a dish) to the highest point of the material at the edges. It is desirable to keep the dish height, DH, as low as possible.

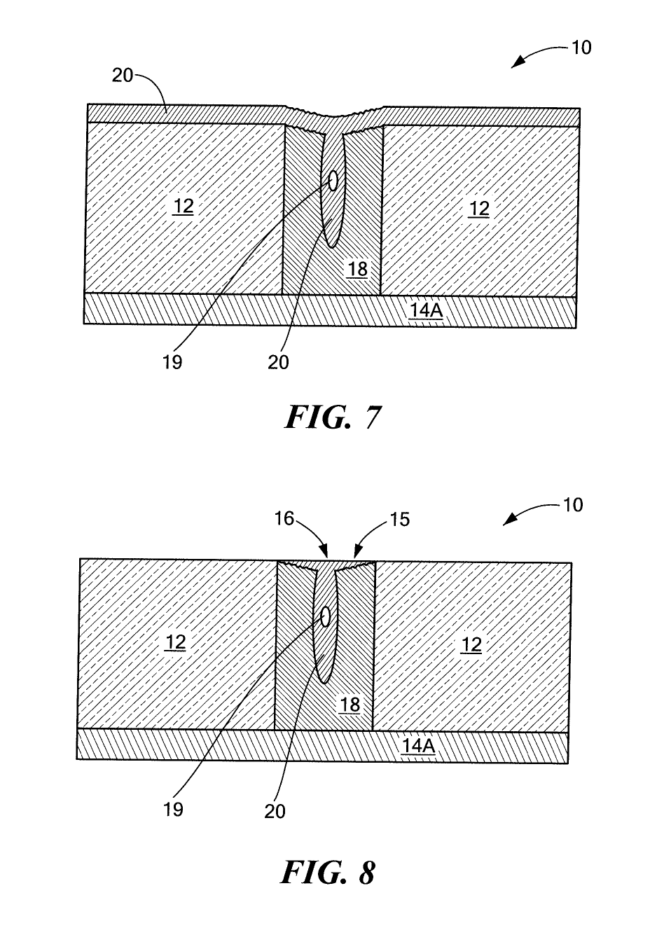

FIG. 7 depicts the integrated circuit 10 after deposition of the second conductive material 20. The second conductive material 20 is deposited on the integrated circuit 10 in much the same way as first conductive material 18 was, as described with respect to FIG. 4. For example, the second conductive material 20 may be deposited using vapor deposition. The deposition of the second conductive layer forms a conductive film of about 200 Angstroms to about 1,000 Angstroms. In one particular example, the deposition of the second conductive material 20 is performed using a PVD process.

The second conductive material 20 fills at least a portion of the hole 15 that is no longer filled with the first conductive material 18. In one particular example, the second conductive material 20 partially fills the cavity 19. In other examples, the cavity 19 is completely filled (see FIG. 1B, for example, showing no cavity in the via 16). The second conductive material 20 also fills the “dished” portion created by CMP, as described with respect to FIGS. 5 and 6. Additionally, the second conductive material 20 also covers the integrated circuit 10 that are not within the border 17, which is an undesirable feature.

In one example, the second conductive material 20 may be a refractory metal, such as titanium nitride, tungsten, or copper. The second conductive material 20 need not be made from the same material as the first conductive material 18. For example, the second conductive material 20 may be made from titanium nitride, whereas the first conductive material 18 is made from tungsten. In other examples, the second conductive material 20 may be made from the same material as the first conductive material 18. In one particular example, the second conductive material 20 and the first conductive material 18 may both be made from titanium nitride.

FIG. 8 depicts the integrated circuit 10 after a second CMP to form the via 16. The via 16 includes the first conductive material 18 electrically connected to the second conductive material 20. The second conductive material 20 has been removed by CMP from the surface of the isolation material 12. As a result, integrated circuit 10 has a substantially smooth surface. CMP enables an upper surface of the second conductive material 20 to be flush with a top surface of the isolation material 12. This results in the integrated circuit 10 having a smooth surface on the top (with respect to FIG. 5), without significant dishing or significant roughness along the portion of the surface of the integrated circuit 10 defined by the via 16. In one particular example, the second conductive material 20 may have a lower rate of removal under chemical-mechanical polishing than the first conductive material 18. In some examples, the CMP may polish the conductive material 20 within the hole 15 of the isolation material 12.

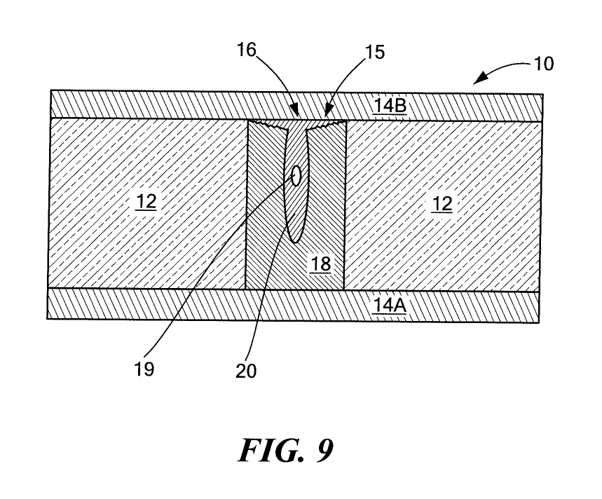

FIG. 9 depicts the trace 14B added to the IC 10. The via 16 has a substantially flatter profile, flush with the surface of the isolation material 12, than other vias made using traditional techniques, by virtue of the processes disclosed herein. Often, these other vias include a “dished” shape, wherein portions of these other vias along the surface of the integrated circuit are recessed.

These portions are recessed more heavily with greater distance from the sides of the border 17, which, in the case of a circular aperture, leads to a dish-shaped surface. Dishing in the traditional vias could have a dish height, DH, as large as 600 Angstroms, whereas the vias made using the techniques described herein may be substantially flat and coplanar with the rest of simple integrated circuit 10, defined as having dish height of 100 Angstroms or less.

Additionally, the via 16 has a surface with a reduced roughness (i.e., a smoother surface) as compared to those other vias made using traditional techniques. Often, these other vias included rough or uneven profiles. This roughness is a byproduct of CMP interacting with the first conductive material 18. Roughness and/or unevenness of the profile of the via may result in improper seating and/or damage to components connected to the via, such as the trace 14B (e.g., a trace 14B that is a GMR component). However, vias 16 made using the techniques described herein are substantially smooth. For example, the adjacent peak-to-valley height of the roughness of traditional vias may be up to 150 Angstroms, whereas vias 16 made using the techniques described herein may be substantially smooth, defined as adjacent peak-to-valley heights of less than 50 Angstroms. By reducing roughness and dishing along the surface of the isolation material 12 at the via 16, components (e.g., the trace 14B) connected to the via 16 may be less prone to failure.

The processes described herein are not limited to the specific examples described. For example, the process 200 is not limited to the specific processing order of FIG. 2. Rather, any of the processing blocks of FIG. 2 may be re-ordered, combined or removed, performed in parallel or in serial, as necessary, to achieve the results set forth above. Also, processing blocks may be added to process 200. For example, prior to depositing the first conductive material 18, a conductive liner may be added. In one particular example, the liner may be deposited using sputtering. In one particular example, the liner may include at least one of titanium and titanium nitride.

Elements of different embodiments described herein may be combined to form other embodiments not specifically set forth above. Other embodiments not specifically described herein are also within the scope of the following claims.

What is claimed is:

1. A method of fabricating a via in a hole of an isolation material, the method comprising:
depositing a first conductive material in the hole of the isolation material;
removing a portion of the first conductive material deposited in the hole;
depositing a second conductive material on the first conductive material in the hole; and
removing, using chemical-mechanical polishing (CMP), a portion of the second conductive material deposited on the first conductive material.

2. The method of claim 1, further comprising:
depositing the first conductive material on a surface of the isolation material;
removing the first conductive material on the surface of the isolation material;
depositing the second conductive material on the surface of the isolation material; and
removing, using chemical-mechanical polishing (CMP), the second conductive material on the surface of the isolation material.

3. The method of claim 1, wherein depositing the first conductive material comprises depositing the first conductive material using vapor deposition.

4. The method of claim 1, wherein depositing the first conductive material comprises depositing the first conductive material into the hole to form a cavity.

5. The method of claim 1, wherein depositing the first conductive material comprises depositing a refractory metal.

6. The method of claim 4, wherein depositing a refractory metal comprises depositing a material from the group consisting of titanium nitride and tungsten.

7. The method of claim 1, wherein removing the portion of the first conductor comprises removing the portion of the first conductor using chemical-mechanical polishing.

8. The method of claim 1, wherein depositing a second conductive material comprises depositing a refractory metal.

9. The method of claim 7, wherein depositing a refractory metal comprises depositing titanium nitride.

10. The method of claim 1, wherein removing the portion of the first conductive material deposited in the hole comprises forming dishing in the first conductive material.

11. The method of claim 1, wherein depositing a first conductive material in the hole of the isolation material comprises depositing a first conductive material in the hole of a material comprising a silicon oxide.

12. The method of claim 11, wherein depositing a first conductive material in the hole of a silicon oxide comprises depositing a first conductive material in the hole of a material comprising silicon dioxide.

13. The method of claim 1, wherein depositing a first conductive material in the hole of the isolation material comprises depositing a first conductive material in the hole of a material comprising silicon nitride.

14. The method of claim 1, wherein depositing a first conductive material in the hole of the isolation material comprises depositing a first conductive material in the hole of a material comprising aluminum oxide.

15. The method of claim 1, further comprising depositing a magnetoresistive material on the via.

16. The method of claim 15, wherein depositing a magnetoresistive material on the via comprises depositing one of a giant magnetoresistance (GMR) element, an anisotropic magnetoresistance (AMR) element, a tunneling magnetoresistance (TMR) element, a magnetic tunnel junction (MTJ) element, or a spin valve element.

17. The method of claim 1, wherein depositing the first conductive material comprises depositing a first conductive material having a first rate of removal under CMP, wherein depositing the second conductive material comprises depositing a second conductive material having a second rate of removal under CMP, the second rate of removal being slower than the first rate of removal.

18. The method of claim 1, wherein depositing the second conductive material comprises depositing the second conductive material using vapor deposition.

19. The method of claim 1, wherein depositing the first conductive material comprises depositing tungsten, and wherein depositing the second conductive material comprises depositing titanium nitride.

20. A via disposed in a hole of an isolation material having a first surface, the via comprising:
a first conductive material disposed in the hole; and
a second conductive material disposed on the first conductive material in the hole, the first and second conductive material forming an electrical connection.

21. The via of claim 20, wherein the first conductive material and the second conductive material are made of the same material.

22. The via of claim 21, wherein the first conductive material and the second conductive material are titanium nitride.

23. The via of claim 20, wherein the first conductive material is a refractory metal.

24. The via of claim 20, wherein the first conductive material is made of a different material than the second conductive material.

25. The via of claim 24, wherein the first conductive material is tungsten and the second conductive material is titanium nitride.

26. The via of claim 20, wherein and the second conductive material is flush with the first surface.

27. The via of claim 20 wherein the isolation material comprises at least one of aluminum oxide, silicon nitride and silicon dioxide.

28. A semiconductor device, comprising:
a silicon dioxide layer having a first surface and a second surface opposite the first surface;
a via disposed in a hole of the silicon dioxide layer, the via comprising:
a tungsten material disposed in the hole; and
a titanium nitride material disposed on the tungsten material, the tungsten material and the titanium nitride material forming an electrical connection;
an aluminum copper layer disposed along the first surface of the silicon dioxide layer and electrically connected to the tungsten material; and
a magnetoresistive element disposed along the second surface of the silicon dioxide layer and electrically connected to the titanium nitride material.

29. The semiconductor device of claim 28, wherein the magnetoresistive material comprises one of a giant magnetoresistance (GMR) element, an anisotropic magnetoresistance (AMR) element, a tunneling magnetoresistance (TMR) element, a magnetic tunnel junction (MTJ) element and a spin valve element.

30. The semiconductor device of claim 29, wherein the magnetoresistive element is a stack of layers comprising at least one of nickel iron (NiFe), cobalt iron (CoFe), copper, platinum manganese (PtMn), tantalum, or ruthenium.
